(19) United States
(12) Patent Application Publication
(10) Pub. No.: US 2008/0212719 A1
(43) Pub. Date: Sep. 4, 2008

(54) Motion vector detection apparatus, and image coding apparatus and image pickup apparatus using the same

(76) Inventors: Shigeyuki Okada, Ogaki-shi (JP); Mitsuru Suzuki, Kariya-Shi (JP)

Correspondence Address: MCDERMOTT WILL & EMERY LLP, 600 13TH STREET, N.W., WASHINGTON, DC, 20005-3096, US

(21) Appl. No.: 12/073,052

(22) Filed: Feb. 28, 2008

(30) Foreign Application Priority Data
Feb. 28, 2007 (JP) 2007-050111

(51) Int. Cl. H04L 27/06; H03D 1/00

(52) U.S. Cl. 375/340; 382/100; 382/236; 375/240.16

(57) ABSTRACT

A search range setting unit sets a search range to be matched with a targeted region of an image to be coded, in a reference image. A computing unit performs computation in a manner such that matching between the targeted region and a region within the search range is computed from a resolution lower than that of an original image toward the resolution of the original image over a plurality of hierarchies and the search range is narrowed. The search range setting unit sets a plurality of search ranges in the reference image in at least one of the plurality of hierarchies.

### CROSS-REFERENCE TO RELATED APPLICATIONS

This application is based upon and claims the benefit of priority from the prior Japanese Patent Application No. 2007-050111, filed on Feb. 28, 2007, the entire contents of which are incorporated herein by reference.

### BACKGROUND OF THE INVENTION

1. Field of the Invention

The present invention generally relates to a motion vector detection technology and it particularly relates to a motion vector detection apparatus for detecting an inter-frame motion vector to code moving images by using an image coding method including an inter-frame prediction mode, and an image coding apparatus and an image pickup apparatus using said motion vector detection apparatus.

2. Description of the Related Art

In MPEG (Motion Picture Experts Group) which is a standard for compressing and coding the moving images, motion-compensated predictive coding is performed using a motion vector. As a technique to detect the motion vector, proposed is a hierarchical motion vector detection method where a reduced image is generated by lowering the resolution of an image to be coded so as to detect an approximate motion vector by use of the reduced image and then the motion vector is detected by use of an image having an original resolution while the approximate motion vector is being referred to.

The hierarchical motion vector detection method can realize the detection of the motion vector with a small computation amount. However, this hierarchical motion vector detection method involves a processing for computing the matching between a reduced image in a search region and a reduced image of an original image. This processing necessarily contains a processing for computing the matching between images of low definition. The reduction in definition leads to increasing the occurrence of like patterns, so that search error is more likely to occur. In particular, once a first research error has occurred, the search processing subsequent to the hierarchy would search for erroneous regions, thus causing a significant error in the search result.

### SUMMARY OF THE INVENTION

A motion vector detection apparatus according to one embodiment of the present invention is an apparatus for detecting from a reference image a motion vector of a targeted region of an image to be coded, and the apparatus comprises: a search range setting unit which sets a search range to be matched with the targeted region, in the reference image; and a computing unit which performs computation in a manner such that matching between the targeted region and a region within the search range is computed from a resolution lower than that of an original image toward the resolution of the original image over a plurality of hierarchies and the search range is narrowed.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 illustrates a general structure of an image pickup apparatus according to an embodiment of the present invention;

FIG. 2 illustrates an internal structure of a motion vector detection circuit according to a first exemplary embodiment;

FIG. 3A shows how a first search range and a second search range required by a primary search are set within a reference image; and FIG. 3B illustrates a result of the primary search in the first search range and the second search range;

FIG. 4A shows how a third search range is set with a first optimum point as a starting point and a fourth search range is set with a second optimum point as a starting point; and FIG. 4B shows how a fifth search range corresponding to the third search range is set and a sixth search range corresponding to the fourth search range is set;

FIG. 5 is a flowchart showing a procedure for detecting a motion vector, according to a first exemplary embodiment;

FIG. 6 illustrates an internal structure of a motion vector detection circuit according to a second exemplary embodiment; and

FIG. 7 illustrates a procedure for detecting a motion vector, according to a second exemplary embodiment.

### DETAILED DESCRIPTION OF THE INVENTION

The invention will now be described by reference to the preferred embodiments. This does not intend to limit the scope of the present invention, but to exemplify the invention.

A description of a typical embodiment will be given before describing a detailed description of embodiments of the present invention. A motion vector detection apparatus according to one embodiment of the present invention is an apparatus for detecting from a reference image a motion vector of a targeted region of an image to be coded, and the apparatus comprises: a search range setting unit which sets a search range to be matched with the targeted region, in the reference image; and a computing unit which performs computation in a manner such that matching between the targeted region and a region within the search range is computed from a resolution lower than that of an original image toward the resolution of the original image over a plurality of hierarchies and the search range is narrowed. The search range setting unit sets a plurality of search ranges in the reference image in at least one of the plurality of hierarchies. The “targeted region” may be a macroblock.

In a process of narrowing the search range over a plurality of hierarchies, a plurality of search ranges are set. Thereby, error in the matching can be reduced. Hence, the optimum motion vector can be accurately detected with a small amount of computation.

In a hierarchy where matching is to be computed at first, the search range setting unit may set a first search range, including a region corresponding to the targeted region and a region adjacent thereto, and a second search range having a region larger than the first search range, in the reference image. As a result, whether an object is at rest or not can be determined promptly.

The motion vector detection apparatus may further comprise an estimation unit which estimates a region having a highest degree of matching with the targeted region, in the reference image. In a hierarchy where matching is to be computed at first, the search range setting unit may set a first search range containing the region estimated by the estimation unit and a second search range containing a region corresponding to the targeted region, in the reference image. Thereby, the possibility that the optimum motion vector is detected promptly can be raised.

The estimation unit may estimate the region having a highest degree of matching by referring to an amount of movement of an image pickup apparatus that mounts the motion vector detection apparatus or by referring to a motion vector of a region adjacent temporally or spatially to the targeted region. By referring to such information, the estimation accuracy can be enhanced.

Another embodiment of the present invention relates to an image coding apparatus. This apparatus comprises: the above-described motion vector apparatus; and a coding unit which codes the image by using the motion vector detected by the motion vector detection apparatus.

According to this embodiment, the image coding apparatus can be structured where the optimum motion vector can be accurately detected with a small amount of computation.

Still another embodiment of the present invention relates to an image pickup apparatus. This apparatus includes: an image pickup device and; the above-described motion vector detection apparatus, wherein the motion vector detection apparatus detects a motion vector of an image retrieved from the image pickup device.

According to this embodiment, the image pickup apparatus can be structured where the optimum motion vector can be accurately detected with a small amount of computation.

Arbitrary combinations of the aforementioned constituting elements, and the implementation of the present invention in the form of a method, an apparatus, a system, a program and so forth may also be effective as and encompassed by the embodiments of the present invention.

The image coding apparatus according to an embodiment of the present invention first generates a reduced image whose resolution has been reduced from an image to be coded. After detecting, by use of the reduced image, a general motion vector whose resolution is low, the coding apparatus detects a motion vector by using an original image whose resolution is high while its approximate motion vector is being referred to. In the present embodiment, a technique is proposed where the optimum motion vector can be detected with accuracy when such a hierarchical motion vector detection technique is employed.

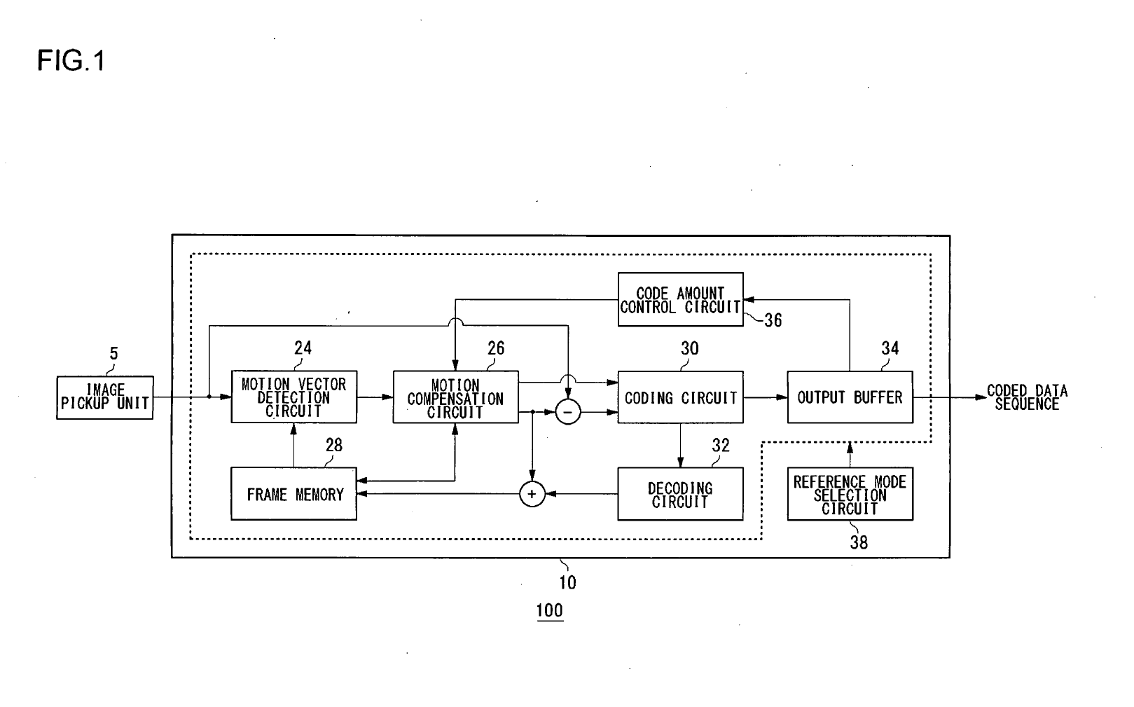

FIG. 1 illustrates a general structure of an image pickup apparatus 100 according to an embodiment of the present invention. The image pickup apparatus 100 is comprised of an image pickup unit 5 and an image coding apparatus 10. The image coding apparatus 10 includes a motion vector detection circuit 24, a motion compensation circuit 26, a frame memory 28, a coding circuit 30, a decoding circuit 32, an output buffer 34, a code amount control circuit 36, and a reference mode selection circuit 38. This structure may be implemented hardwarewise by elements such as a CPU, memory and other LSIs of an arbitrary computer, and softwarewise by memory-loaded programs or the like. Depicted herein are functional blocks implemented by cooperation of hardware and software. Therefore, it will be obvious to those skilled in the art that the functional blocks may be implemented by a variety of manners including hardware only, software only or a combination of both.

The image pickup unit 5, which is comprised of image pickup devices such as CCD (Charge-Coupled Devices) sensors and CMOS (Complementary Metal-Oxide Semiconductor) image sensors, converts images picked up by the image pickup devices into electric signals and outputs them to the image coding apparatus 10 as an input image. The motion vector detection circuit 24 detects a motion vector between the input image and an image to be referenced for prediction (this image is stored beforehand in the frame memory 28 and hereinafter will be referred to as “reference image). The motion compensation circuit 26 acquires from the code amount control circuit 36 a value of quantization step used for quantization, and determines quantization coefficients therefor and a prediction mode of macroblock. The motion vector detected by the motion vector detection circuit 24 and the quantization coefficients determined by the motion compensation circuit 26 are sent to the coding circuit 30. Also, the motion compensation circuit 26 sends to the coding circuit 30 a difference between a predicted value and an actual value of the macroblock, as a prediction error.

The coding circuit 30 codes the prediction error by using the quantization coefficients so as to be outputted to the output buffer 34. The coding circuit 30 sends the quantized prediction error and the quantization coefficients to the decoding circuit 32. The decoding circuit 32 decodes the quantized prediction error, based on the quantization coefficients, and sends the sum of the decoded prediction error and the predicted value sent from the motion compensation circuit 26, to the frame memory 28 as a decoded image. This decoded image is sent to the motion vector detection circuit 24 as a reference image when it is referenced in a subsequent image coding processing. The code amount control circuit 36 acquires the current level of accumulated storage of the output buffer 34, and generates a value of quantization step to be used for the next quantization, according to said level of accumulated storage.

The reference mode selection circuit 38 switches the frame prediction mode among intra-frame coding, inter-frame forward predictive coding and inter-frame bidirectional predictive coding, and outputs information on the frame prediction mode to the other circuits.

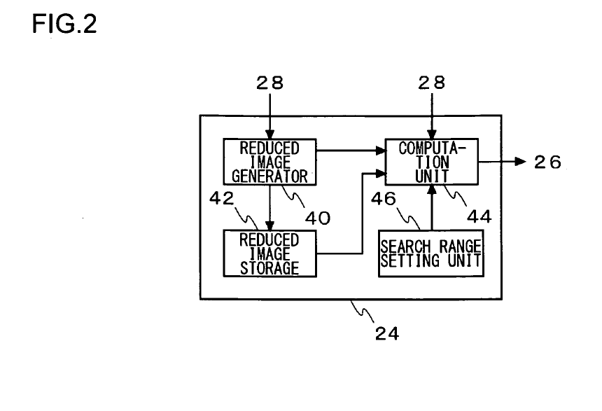

FIG. 2 illustrates an internal structure of the motion vector detection circuit 24 according to a first exemplary embodiment. The motion vector detection circuit 24 includes a reduced image generator 40, a reduced image storage 42, a computation unit 44, and a search range setting unit 46. The reduced image generator 40 acquires an input image and a reference image both stored in the frame memory 28, lowers the resolution of the images and generates images which are reduced in size up to a predetermined scaling factor. The reduced image generator 40 may reduce the images by thinning out the pixels. The reduced image generator 40 may take an average of pixel data contained in a block of a predetermined size so as to set said block as a pixel. In this manner, the reduced image generator 40 may generate the reduced images by using an arbitrary technique. The computation unit 44 calculates a difference between a macroblock of an input image to be coded (hereinafter referred to as “macroblock to be coded”) and a macroblock within the search range of the reference image, where such a difference is hereinafter referred to as “prediction error”. And the computation unit 44 detects a motion vector in a manner that a macroblock of the reference image, having the minimum prediction error, whose degree of matching is highest is searched.

The search range setting unit 46 defines a plurality of search ranges within a reference image and sets them in the computation unit 44. For example, the search range setting unit 46 defines a first search range where a comparatively large area around a macroblock (as a center) to be coded is set up and a second search range where a relatively small area adjacent to an area around the macroblock (as a center) to be coded is set up. Details on the setting of the search ranges will be discussed later. The reduced image storage 42, which is constituted by memories such as SDRAM, stores part or whole of reduced images generated by the reduced image generator 40. The reduced image storage 42 may be realized by part of the frame memory 28 or shared with the frame memory 28.

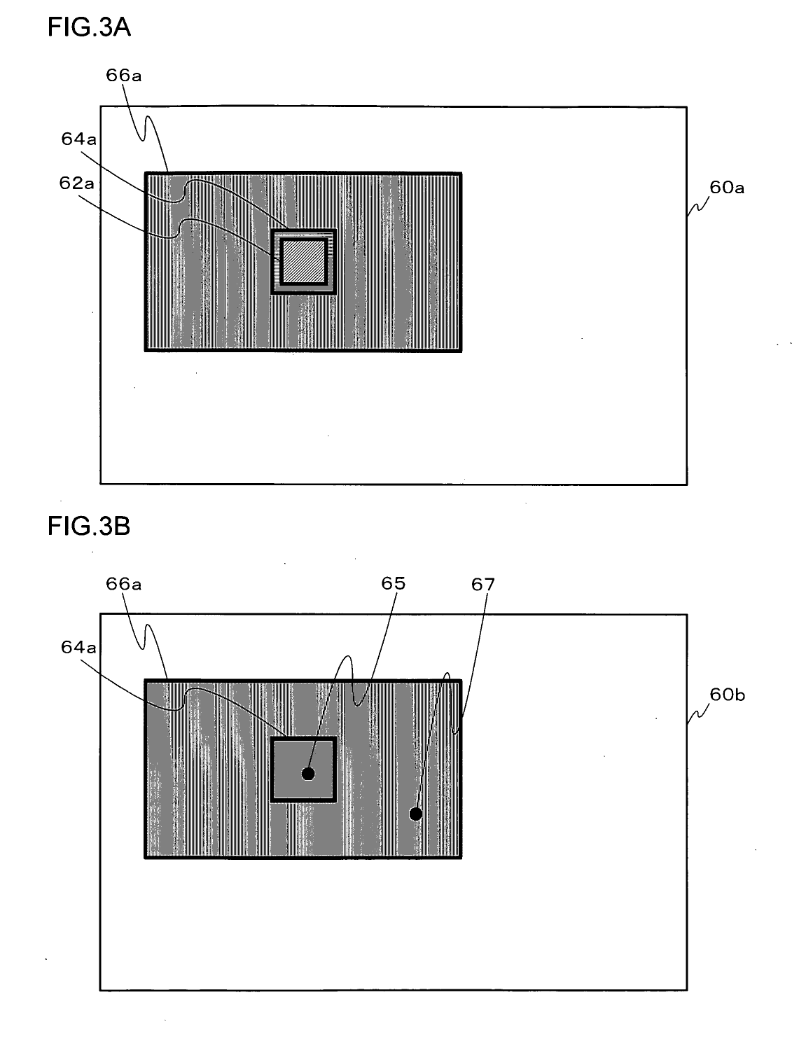

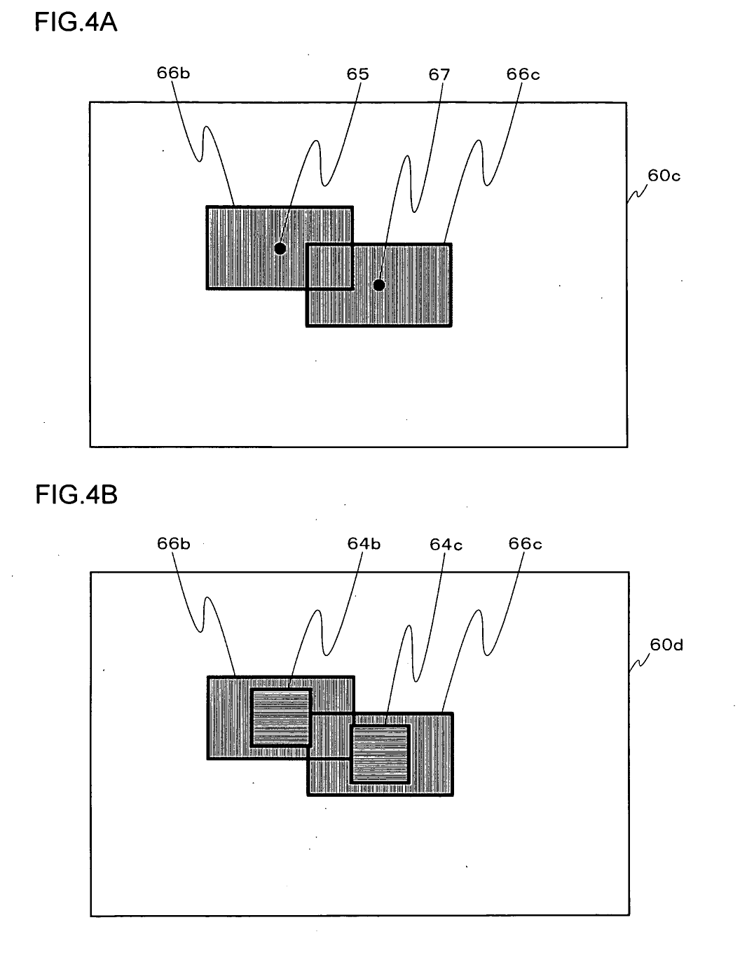

FIGS. 3A and 3B and FIGS. 4A and 4B illustrates procedures for detecting a motion vector according to the first exemplary embodiment. In the following example, a search is conducted over three hierarchies. Firstly, as a primary search, a macroblock to be coded and an image in the search range are each reduced by a factor of ¼ so as to search an optimum point. Then, as a secondary search, they are each reduced by a factor of ½ so as to search an optimum point. Lastly, as a third search, an optimum point in the resolution of original images is searched so as to detect a motion vector.

FIG. 3A shows how a first search range 64a and a second search range 66a required by the primary search are set within a reference image 60a. In the reference image 60a, the search range setting unit 46 sets the first search range 64a and the second search range 66a each containing a macroblock 62a lying in the same position as the macroblock of an image to be coded. In this example, the size of each macroblock to be coded in the original image is set to 16×16 pixels (vertically and horizontally). Thus, the size of said macroblock 62a is set to 16×16 pixels (vertically and horizontally), too. The first search range 64a occupies 4 pixels in the horizontal direction and 4 pixels in the vertical direction around said macroblock 62a being the center, so that 24×24 pixels are set vertically and horizontally. The second search range 66a occupies 48 pixels in the horizontal direction and 24 pixels in the vertical direction around said macroblock 62a being the center, so that 64×112 pixels are set vertically and horizontally.

The number of pixels can be set arbitrarily by a designer as long as the number of pixels of the first search range 64a is less than that of the second search range 66a. Since the primary search is the coarsest research among the hierarchical motion vector detection methods, it is desirable that the number of pixels of the second search range 66a be set to a relatively large number. For example, the number of pixels of the second search range 66a may be set based on the maximum panning amount attainable by an image pickup apparatus mounted on the image coding apparatus 10. Also, the number of pixels may be controlled variably according to the image shooting mode of the image pickup apparatus. The first search range 64a is a region primarily used to determine if an object captured on a macroblock to be coded remains stationary or not and used to determined if the aforementioned image pickup apparatus remains stationary or not. Thus, the number of pixels of the first search range 64a may be relatively small.

In order to reduce the original image to ¼ in the primary search, the reduced image generator 40 reads out the pixel data of the macroblock of the input image to be coded, from the frame memory 28 and reduces the image by a factor of ¼ so as to generate a reduced image of 4×4 pixels (in height and width). The reduced image generator 40 reads out the pixel data of the first search range 64a from the frame memory 28 and reduces the image by a factor of ¼ so as to obtain a reduced image of 6×6 pixels (in height and width). Similarly, the reduced image generator 40 reads out the pixel data of the second search range 66a from the frame memory 28 and reduces the image by a factor of ¼ so as to obtain a reduced image of 16×28 pixels (in height and width).

FIG. 3B illustrates a result of the primary search in the first search range 64a and the second search range 66a. In the reference image 60b, the computation unit 44 searches for an optimum block where the prediction error thereof from the macroblock to be coded which has been reduced to ¼ is minimum in the first search range 64a which has been reduced to ¼. Hereinbelow, a point of interest, such as a central coordinate of this optimum block, is called a first optimum point 65. A difference between the first optimum point 65 and a corresponding point of interest of the aforementioned macroblock 62a is a first approximate motion vector in the primary search. Similarly, the computation unit 44 searches for an optimum block where the prediction error thereof from the macroblock to be coded which has been reduced to ¼ is minimum in the second search range 66a which has been reduced to ¼. Hereinbelow, a point of interest, such as a central coordinate of this optimum block, is called a second optimum point 67. A difference between the second optimum point 67 and a corresponding point of interest of the aforementioned macroblock 62a is a second approximate motion vector in the primary search.

FIG. 4A shows how a third search range 66b is set with the first optimum point as a starting point and a fourth search range 66c is set with the second optimum point as a starting point. In a reference image 60c, the search range setting unit 46 sets the third search range 66b around a macroblock (as a center) wherein the first optimum point 65 serves as a point of interest of said macroblock. Similarly, the search range setting unit 46 sets the fourth search range 66c around a macroblock (as a center) wherein the second optimum point 67 serves as a point of interest of said macroblock. The third search range 66b and the fourth search range 66c correspond to the second search range 66a in the primary search.

FIG. 4B shows how a fifth search range 64b corresponding to the third search range 66b is set and a sixth search range 64c corresponding to the fourth search range 66c is set. In a reference image 60d, the search range setting unit 46 sets the fifth search range 64b around a macroblock (as a center) wherein the first optimum point 65 serves as a point of interest of said macroblock. Similarly, the search range setting unit 46 sets the sixth search range 66c around a macroblock (as a center) wherein the second optimum point 67 serves as a point of interest of said macroblock. The relation between the third search range 66b and the fifth search range 64b and the relation between the fourth search range 66c and the sixth search range 64c correspond to the relation between the second search range 66a and the first search range 64a in the primary search.

In order to reduce the size of the original image by a factor of ½ in the secondary search, the reduced image generator 40 reads out the image data of the macroblock of an image to be coded, from the frame memory 28 and reduces the image by a factor of ½ so as to generate a reduced image of 8×8 pixels (in height and width). The search range is narrowed based on a result of the primary search, so that the third search range 66b and the fourth search range 66c are each made narrower than the second search range 66a. For example, suppose that the third search range 66b and the fourth search range 66c are each set to ¼ of the second search range 66a. Then the reduced image generator 40 reads out the third search range 66b and the fourth search range 66c of 32×58 pixels (in height and width) from the frame memory 28, and reduces these images by a factor of ½ so as to obtain a reduced image of 16×29 pixels (in height and width). The reduced image generator 40 reads out image data of the fifth search range 64b and the sixth search range 64c and reduces the images by a factor of ½ so as to obtain images of 12×12 pixels (in height and width). Note that the fifth search range 64b and the sixth search range 64c may be narrower than the first search range 64a.

The computation unit 44 searches for an optimum block having the minimum prediction error thereof from a macroblock to be coded wherein the macroblock to be coded has been reduced by a factor of ½ in the third search range 66b reduced by a factor of ½. Hereinbelow, the point of interest of this macroblock is called a third optimum point. Similarly, the computation unit 44 searches for an optimum block having the minimum prediction error thereof from a macroblock to be coded wherein the macroblock to be coded has been reduced by a factor of ½ in each of the fourth search range 66b, the fifth search range 64b and the sixth search range 64c reduced by a factor of ½. Hereinbelow, the points of interest of these macroblocks are called a fourth optimum point, a fifth optimum point and a sixth optimum point, respectively.

Similarly to the processing where four search ranges have been set with the first optimum point 65 and the second optimum point 67 as starting points obtained in the primary search, eight search ranges are set with the third optimum point, the fourth optimum point, the fifth optimum point and the sixth optimum point as starting points, in the third search. In the third search, the matching is computed while the original image is not subjected to the reduction. In this manner, the optimum points are acquired from the eight search ranges, and a motion vector between a block of the optimum point having the minimum prediction error and a macroblock to be coded is determined as a final motion vector. Though the description has been given of the three hierarchical search, the motion vector can be determined in the second hierarchical search and four or more hierarchical search by using the similar method. In a processing after the secondary search, a search range may be set without setting a plurality of search ranges per optimum point. In such a case, the number of optimum points obtained from the preceding hierarchy is equal to the number of search ranges to be set in the current hierarchy.

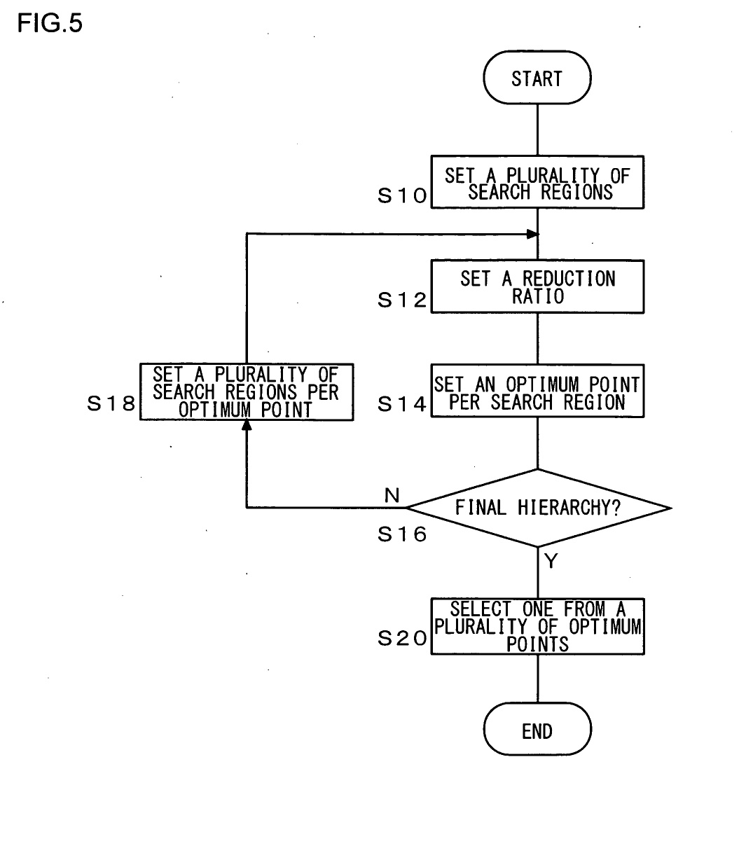

FIG. 5 is a flowchart showing a procedure for detecting a motion vector, according to the first exemplary embodiment. A description is given here of an example where the motion vector of a macroblock to be coded is detected using the search of n hierarchies (n being a natural number). The search range setting unit 46 sets a plurality of search ranges as search ranges of the macroblock to be coded (S10). The reduced image generator 40 reduces the macroblock to be coded and the pixel data in an applicable search range at a reduction ratio corresponding to the current hierarchy (S12). The computation unit 44 detects the optimum point of a macroblock to be coded, per search range (S14). Here, if the prediction error between a block having the optimum point in a certain search range and the macroblock to be coded is zero, the processing may not proceed to the next hierarchy and may determine the motion vector to be zero. Also, in the next hierarchy, a search range may be set only for the optimum point thereof. This is because it is determined that an object in the macroblock to be coded and a point at which the image pickup apparatus is located and shoots the images remain stationary and therefore the other regions do not need to be searched. If the value of prediction error between a macroblock having an optimum point in a certain search range and a macroblock to be coded is not exactly zero (almost zero) but is less than an extremely small threshold value which has been set based on experiments or simulation runs, it may be determined similarly that the motion vector is zero. According to such processings as described above, the amount of computation can be reduced as compared with the processing where the optimum points in a plurality of search ranges are obtained in all of the hierarchies.

After having detected optimum points of other than the n hierarchies (N of S16), the search range setting unit 46 sets a plurality of search ranges as the search ranges of the macroblock to be coded, per optimum point of the current hierarchy (S18). Now, proceed to Step 12 and the subsequent steps. After having detected the optimum points of the n hierarchies (Y of S16), an optimum point having the minimum prediction error is selected among the prediction errors between a plurality of blocks having optimum points in the n hierarchies and the macroblock to be coded (S20). The motion vector between the block having the thus selected optimum point and the macroblock to be coded is determined as the final motion vector.

When in Step 18 the search range setting unit 46 sets a plurality of search ranges from the optimum point of the current hierarchy, it may select the optimum point having the minimum prediction error among the prediction errors between the blocks having those optimum points and the macroblock to be coded and may set a plurality of search ranges for this optimum point only. By performing this processing, the amount computation can be reduced.

According to the first exemplary embodiment as explained above, the motion vector can be accurately detected with a smaller amount of computation. That is, by employing the hierarchical motion vector detection method, the search range can be narrowed based on the result of matching processing between the reduced images, so that the amount of computation can be reduced. Thus, the processing for detecting the motion vector can be performed faster. Also, the possibility that a block other than the optimum block is detected by mistake due to the occurrence of similar patterns can be reduced. The increase in the degree of accuracy of detecting the motion vectors contributes to the improvement of coding efficiency and image quality.

Also, the setting a search range within which a region having some pixels is secured around the macroblock (as a center) to be coded allows determining easily if the image pickup apparatus mounting this image coding apparatus 10 is panning or not. Also, when the image pickup apparatus remains stationary, whether an object is at rest or not can be determined easily. Such information may be used as the information on the setting of the image pickup apparatus and the like. For example, the fact that the panning has been detected can be conveyed to a control system designed for the correction of camera shake.

In many cases, the setting is done so that the first search range and the second search range overlap with each other. Thus, the matching computation results can be shared, so that the amount of computation can be reduced.

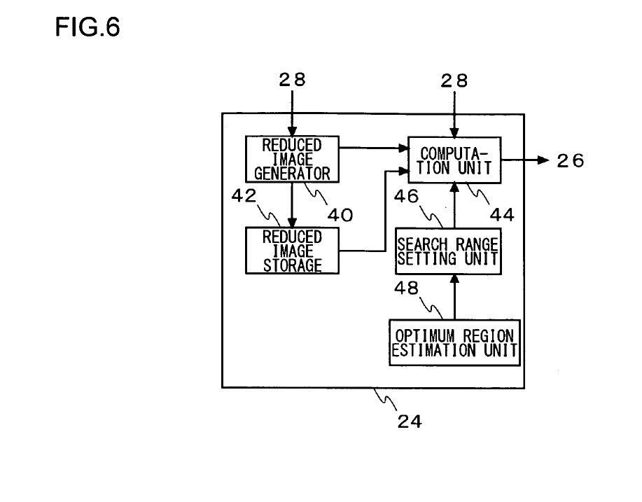

FIG. 6 illustrates an internal structure of motion vector detection circuit 24 according to a second exemplary embodiment. The vector detection circuit 24 according to the second exemplary embodiment is of a structure such that an optimum region estimation unit 48 is added to the motion vector detection circuit 24 of the first exemplary embodiment. The optimum region estimation unit 48 estimates a search range, having a high probability that there exists an optimum block whose prediction error from the block to be coded is minimum, in the reference image and sends it to the search range setting unit 46. For example, if the image pickup apparatus mounted on this image coding apparatus 10 is equipped with a camera shake correction function, the optimum region estimation unit 48 can acquire the amount of movement of the image pickup apparatus from the camera shake correction control system. If this amount of movement indicates that the image pickup apparatus has panned from right to left, it can be estimated that the optimum block may exist in a position moved to the right of the block to be coded.

Also, the optimum region estimation unit 48 can estimate the position of the optimum vector from the motion vector of a macroblock adjacent temporally or spatially to the block to be coded. For example, the optimum region estimation unit 48 may independently refer to the motion vector of a macroblock adjacent thereto, within the same image or may refer to an average value of macroblocks adjacent thereto. Also, the motion vector of the same or adjacent macroblock of a frame immediately before the current frame may be referred to.

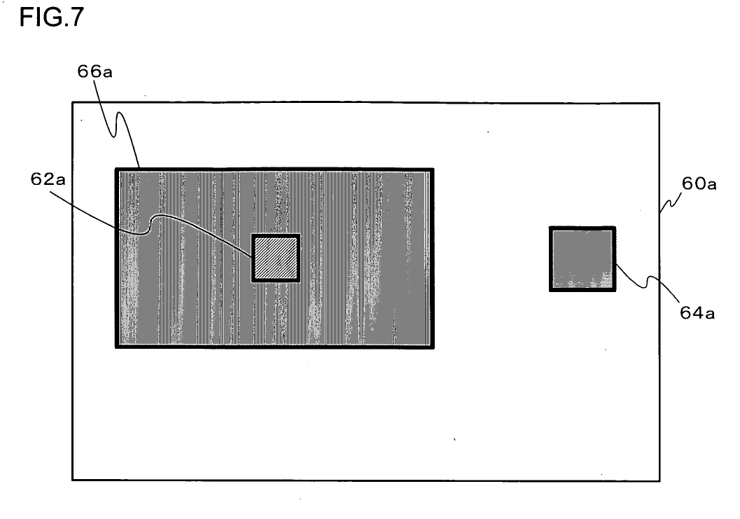

FIG. 7 illustrates a procedure for detecting a motion vector, according to the second exemplary embodiment. The procedure for detecting a motion vector according to the second exemplary embodiment is the same as that according to the first exemplary embodiment. The difference lies in the setting position of the first search range 64a. If the optimum region estimation unit 48 recognizes that the image pickup apparatus has panned from right to left, the optimum region estimation unit 48 will estimate that the optimum block to be coded has moved to the right by an amount with which to offset the amount of movement thereof. And the optimum region estimation unit 48 will set the first search range 64a in a region that contains the thus estimated position. When the object in this block to be coded remains stationary, the probability that the optimum block is detected within the first search range 64a is high. FIG. 7 corresponds to FIG. 3A, and the subsequent processing is the same as the detection procedures shown in FIG. 3A to FIG. 5.

As described above, by employing the secondary embodiment, the motion vector can be accurately detected with a small amount of computation. A search range that contains a spot having a high probability that an optimum block exists is set. Thus, if the optimum block, for example, a block whose prediction error is zero is detected from the search range, the optimum block can be identified without affecting the result of other search ranges, so that a motion vector which is most suitable can be determined.

The description of the invention given above is based upon illustrative embodiments. These exemplary embodiments are intended to be illustrative only and it will be obvious to those skilled in the art that various modifications to constituting elements and processes could be developed and that such modifications are also within the scope of the present invention.

In the preferred embodiments, the setting range of the second search range 66a is set around a block (as a center) corresponding to a block to be coded, within the reference image 60a. However, it may be set in an arbitrary region within the reference image 60a. For example, the above block may lie in a position displaced from the center of the second search range 66a, instead of in the center thereof. Or, said block may exist outside the second search range 66a. The same holds for the search range corresponding to the second search range 66a in other hierarchies.

In the preferred embodiments, two search ranges are set in the primary search but three or more search ranges may also be set. For example, both the first search range 64a set in the first exemplary embodiment and the first search range 64a set in the second exemplary embodiment may be set within the reference range 60a. In such a case, the possibility of detecting a further optimum motion vector can be increased. Though the amount of computation may increase slightly, it is possible to reduce the total amount of computation if the optimum motion vector can be detected in the primary search.

In the first exemplary embodiment, the setting range of the first search range 64a is set around a block (as a center) corresponding to a block to be coded, within the reference image 60a. However, it does not need to be set with the block as the center in the strict sense. It suffices if said block is contained within the setting range of the first search range 64a.

While the preferred embodiments of the present invention have been described using specific terms, such description is for illustrative purposes only, and it is to be understood that changes and variations may be made without departing from the spirit or scope of the appended claims.

What is claimed:

1. A motion vector detection apparatus for detecting from a reference image a motion vector of a targeted region of an image to be coded, the apparatus comprising:
a search range setting unit which sets a search range to be matched with the targeted region, in the reference image; and
a computing unit which performs computation in a manner such that matching between the targeted region and a region within the search range is computed from a resolution lower than that of an original image toward the resolution of the original image over a plurality of hierarchies and the search range is narrowed,
wherein said search range setting unit sets a plurality of search ranges in the reference image in at least one of the plurality of hierarchies.

2. A motion vector detection apparatus according to claim 1, wherein in a hierarchy where matching is to be computed at first, said search range setting unit sets a first search range, including a region corresponding to the targeted region and a region adjacent thereto, and a second search range having a region larger than the first search range, in the reference image.

3. A motion vector detection apparatus according to claim 1, further comprising an estimation unit which estimates a region having a highest degree of matching with the targeted region, in the reference image,
wherein, in a hierarchy where matching is to be computed at first, said search range setting unit sets a first search range containing the region estimated by said estimation unit and a second search range containing a region corresponding to the targeted region, in the reference image.

4. A motion vector detection apparatus according to claim 3, wherein said estimation unit estimates the region having a highest degree of matching by referring to an amount of movement of an image pickup apparatus that mounts said motion vector detection apparatus.

5. A motion vector detection apparatus according to claim 3, wherein said estimation unit estimates the region having a highest degree of matching by referring to a motion vector of a region adjacent temporally to the targeted region.

6. A motion vector detection apparatus according to claim 3, wherein said estimation unit estimates the region having a highest degree of matching by referring to a motion vector of a region adjacent spatially to the targeted region.

7. A motion vector detection apparatus according to claim 1, wherein the targeted region is a macroblock.

8. An image coding apparatus, comprising:
a motion vector apparatus according to claim 1; and
a coding unit which codes the image by using the motion vector detected by said motion vector detection apparatus.

9. An image pickup apparatus, including:
an image pickup device; and
a motion vector detection apparatus according to claim 1,
wherein said motion vector detection apparatus detects a motion vector of an image retrieved from said image pickup device.
